(19) United States
(12) Patent Application Publication
(10) Pub. No.: US 2010/0116338 A1
(43) Pub. Date: May 13, 2010

(54) HIGH QUALITY SEMICONDUCTOR MATERIAL

(75) Inventors: Xixiang Xu, Rochester Hills, MI (US); Subhendu Guha, Bloomfield Hills, MI (US); Chi Yang, Troy, MI (US)

Correspondence Address: GIFFORD, KRASS, SPRINKLE,ANDERSON & CITKOWSKI, P.C, PO BOX 7021, TROY, MI, 48007-7021, US

(73) Assignee: United Solar Ovinic LLC, Auburn Hills, MI (US)

(21) Appl. No.: 12/266,957

(22) Filed: Nov. 7, 2008

(51) Int. Cl. H01L 31/00; C01B 33/04

(52) U.S. Cl. 136/261; 423/347

(57) ABSTRACT

A hydrogenated, silicon based semiconductor alloy has a defect density of less than 10¹⁶ cm⁻³. The alloy may comprise a hydrogenated silicon alloy or a hydrogenated silicon-germanium alloy. Hydrogen content of the alloy is generally less than 15%, and in some instances less than 11%. The tandem photovoltaic devices which incorporate the alloy exhibit low levels of photo degradation. In some instances, the material is fabricated by a high speed VHF deposition process.

### STATEMENT OF GOVERNMENT INTEREST

This invention was made, at least in part, under U.S. Government, Department of Energy, Contact No. DE-FC36-07G017053. The Government may have rights in this invention.

### FIELD OF THE INVENTION

This invention generally relates to thin film materials such as thin film semiconductor materials. More specifically, the invention relates to hydrogenated, silicon based semiconductor materials having high quality electrical and material properties.

### BACKGROUND OF THE INVENTION

The performance characteristics of electronic devices, such as photovoltaic devices, depend, in a large degree, upon the electrical and material properties of the semiconductor materials incorporated into the devices. The performance characteristics of photovoltaic devices include efficiency and stability. The economics of the process for manufacturing such devices will at least in part depend on the efficiency and speed of the methods used for the preparation of the semiconductor materials. Hence, the industry has sought to efficiently manufacture high quality semiconductor materials at high deposition rates.

Plasma deposition processes, also known as glow discharge deposition processes and as plasma assisted chemical vapor deposition processes, are employed for the preparation of thin films of a variety of thin film materials such as semiconductor materials, insulating materials, oxygen and water vapor barrier coatings, optical coatings, polymers and the like. In a typical plasma deposition process, a process gas, which includes at least one precursor of the material being deposited, is introduced into a deposition chamber, typically at subatmospheric pressure. Electromagnetic energy is introduced into the chamber, typically from a cathode which is spaced apart from a substrate upon which the thin film material will be deposited. The electromagnetic energy energizes the process gas so as to generate an excited plasma therefrom. The plasma decomposes the precursor material in the process gas and deposits a coating on the substrate. In some instances, the substrate is maintained at an elevated temperature so as to facilitate the deposition of the thin film material thereupon.

In many instances, the plasma deposition processes are carried out utilizing radio frequency (RF) energy (approximately 13.56 MHz). RF deposition processes have been found to produce high quality semiconductor materials; however, due the relatively low frequency being employed, RF processes typically have relatively low deposition rates. For example, in the preparation of thin film photovoltaic materials such as hydrogenated silicon, germanium, and silicon/germanium alloys, typical deposition rates for RF energized processes are around 1-3 angstroms per second. In many instances, semiconductor devices such as photovoltaic devices employ relatively thick layers of semiconductor material, and these low deposition rates can adversely impact the economics and logistics of large scale device fabrication processes.

Plasma deposition processes energized by higher frequency electromagnetic energy such as very high frequency (VHF) energy typically have higher deposition rates. Consequently, the industry has been exploring the use of VHF deposition processes for preparation of semiconductor layers in those instances where deposition speed is important. In the context of this disclosure VHF deposition processes are understood to be carried out using electromagnetic energy having a frequency in the range of 30-150 MHz.

While it has been known by those skilled in the art that higher frequency excitation could be employed to increase the rate of deposition, research by scientists for the last twenty years has concluded that the highest quality material is made at the slowest rate of deposition. For instance, research by Canon, Inc. and others have shown that silicon alloy material could be deposited using microwave frequencies at rates an order of magnitude or more greater than those rates obtained with RF frequencies; however the resulting silicon alloy material was of inferior quality having a higher density of defect states and hence poorer minority carrier lifetimes.

Furthermore, it has been found that while semiconductor materials prepared by a VHF process carried out at a high deposition rate are of higher quality than those prepared by a comparable high deposition rate RF process, those high rate materials are inferior to semiconductor materials prepared by a low deposition rate RF process. Conventional wisdom has also held that in those instances where VHF is employed in a deposition system, the spacing between the cathode or other source of power and the substrate must be less than the distance in a comparable RF energized deposition process. For example, in an RF energized process the cathode to substrate spacing may be approximately 25-50 millimeters whereas conventional wisdom has held that in a VHF process, substrate spacing must be decreased as compared to a comparable RF process. Conventional wisdom has also held that as the spacing between the source of electromagnetic energy (such as a cathode) and the substrate is decreased, the pressure of the working gas used to form the plasma must be increased. For example, the publication “Improved Crystallinity of Microcrystalline Silicon Films Using Deuterium Dilution”, Mat. Res. Soc. Symp. Proc. Vol. 609 at 2000 Materials Research Society, Suzuki et al. (2000) describes a plasma deposition process for producing microcrystalline silicon materials utilizing 60 MHz electromagnetic energy at an operating pressure of 2 torr and a cathode substrate spacing of 17 millimeters.

As noted above, the prior art has generally found that semiconductor materials prepared by high deposition rate VHF processes are inferior to those prepared utilizing low deposition rate RF processes. It is also conventional wisdom that high speed plasma deposition processes must be carried out utilizing high substrate temperatures in order to obtain similar quality of semiconductor materials deposited thereby. For example, U.S. Pat. Nos. 5,346,853 and 5,476,798 teach that in order to produce high quality semiconductor material, substrate temperature must be increased as the deposition rate increases in a plasma deposition process. As a consequence, the prior art typically employs substrate temperatures in excess of 300° C., and in some instances as high as 500° C., for the high rate deposition of silicon based semiconductor materials.

As a consequence, artisans in the field of semiconductor deposition technologies have heretofore held that in the preparation of semiconductor materials, and in particular hydrogenated silicon and silicon-germanium alloys, in a VHF energized, plasma enhanced, chemical vapor deposition process, the process must be carried out utilizing relatively small cathode-substrate spacing, at relatively high substrate temperatures, typically in excess of 300° C., and at relatively high pressures. Furthermore, the prior art has believed that materials had to be deposited at relatively low deposition rates if high quality semiconductor material is desired. These prior art established parameters imposed undue limitations on the high volume manufacture of large area semiconductor devices such as photovoltaic devices.

For example, photovoltaic materials are advantageously prepared in a continuous deposition process, wherein a web of substrate material is continuously advanced through a series of plasma deposition stations. Some such processes are shown in published U.S. patent applications 2004/0040506 filed Aug. 27, 2002, entitled “High Throughput Deposition Apparatus” and 2006/0278163 filed Mar. 16, 2006, entitled “High Throughput Deposition Apparatus with Magnetic Support”. The disclosures of these patent applications are incorporated herein by reference. If the space in between the deposition cathode and the web of substrate material is relatively narrow, a complicated web drive and handling system will be required to maintain the close substrate cathode spacing. (This is true not only because of “wiggle” or “canoeing” of the web over long distances, but also because the depositing material builds up on the wall of the cathode over the lengthy period of continuous deposition and can scratch the web if the distance is too narrow.) Also, requirements of maintaining a high substrate temperature can complicate the process and cause degradation problems with regard to previously deposited semiconductor layers. Furthermore, higher process gas pressures can lead to polymerization and powder formation as well as plasma instabilities which make the deposition process more difficult to control. As a consequence of the foregoing, VHF energized deposition processes have had limited utility in the commercial scale preparation of large area semiconductor devices, particularly silicon alloy semiconductor material; and most particularly silicon germanium alloy semiconductor material.

As will be explained in detail hereinbelow, the present invention represents a break with the prior art insofar as it recognizes that high quality semiconductor materials may be deposited at high deposition rates in a VHF energized plasma deposition process carried out outside the parameters dictated by the prior art. As such, the present invention provides a high speed VHF energized deposition process which is operative to produce semiconductor materials which equal, or exceed, like materials produced in a comparatively slower RF energized deposition process. These and other advantages of the invention will be apparent from the discussion and description which follow.

### BRIEF DESCRIPTION OF THE INVENTION

Disclosed herein is a hydrogenated, silicon based semiconductor alloy having a defect density of less than 10¹⁶ cm⁻³. In particular instances, the semiconductor alloy is a hydrogenated silicon-germanium alloy. The alloy may, in some instances, have a defect density of less than 8×10¹⁵ cm⁻³, while in other instances, the defect density is approximately 7×10¹⁵ cm⁻³. In some instances, the semiconductor alloys have a hydrogen content of less than 15%, and in specific instances, the hydrogen content is less than 11%.

Further disclosed are hydrogenated, silicon based semiconductor alloys characterized in that when the alloy comprises the i layer of a p-i-n type photovoltaic cell, that cell manifests a photo-induced degradation of less than 15% when exposed to A.M. 1.5 illumination for 1,000 hours at 50° C. The alloy material may further be characterized in that when it comprises one of the i layers in a triple junction photovoltaic cell, that cell manifests a photo-induced degradation of less than 10% when exposed to A.M. 1.5 illumination for 1,000 hours at 50° C. Also, the alloy may be characterized in that when it comprises one of the i layers in a tandem junction photovoltaic cell, that cell manifests a photo-induced degradation of less than 15% when exposed to A.M. 1.5 illumination for 1,000 hours at 50° C.

In particular instances, the semiconductor material is characterized in that at least a portion thereof has a microstructure configured as a plurality of columns separated by microvoids.

Further disclosed are photovoltaic devices which include the novel semiconductor material of the instant invention.

Also disclosed herein are semiconductor alloy materials made by a method which comprises a high speed plasma assisted chemical vapor deposition process. The method comprises: providing a deposition chamber, disposing a cathode in the chamber, disposing a substrate in the chamber so that the substrate is spaced from the cathode by a distance in the range of 10-50 millimeters. The method further includes introducing a process gas, which includes at least one component of the semiconductor material, into the chamber. The process gas is maintained at a pressure in the range of 0.5-2.0 torr and the substrate is maintained at a temperature which is less than 300° C. The cathode is energized with VHF electromagnetic energy so as to generate a plasma from said process gas, in the region between the substrate and the cathode, so as to deposit a layer of semiconductor material onto the substrate at a deposition rate of at least 5 angstroms per second.

In a typical process the VHF electromagnetic energy has a frequency in the range of 30-150 MHz. In particular instances, the substrate is spaced from the cathode by a distance in the range of 20-30 millimeters, and in a specific instance a distance of 22-28 millimeters. In particular instances, the process is operative to deposit a hydrogenated silicon semiconductor, and the process gas will include at least silicon and hydrogen. In other instances, the process is operative to deposit a hydrogenated silicon-germanium alloy, and the process gas will include at least silicon, germanium, and hydrogen.

In some instances, the process comprises a continuous deposition process wherein a body of substrate material is continuously advanced through the deposition chamber, relative to the cathode, so that the layer of semiconductor material is deposited onto the substrate as it advances relative to the cathode.

### DETAILED DESCRIPTION OF THE INVENTION

A first aspect of the present invention is directed to a plasma deposition process for the preparation of thin film material such as semiconductor materials, and a second aspect is directed to particular, high quality semiconductor materials which may, but need not be, manufactured by the process. In the process of the present invention, the plasma is created by very high frequency (VHF) electromagnetic energy, which is understood to mean electromagnetic energy having a frequency in the range of 30-150 MHz, and in particular instances a frequency in the range of 40-120 MHz. The process of the present invention will be described primarily with reference to a process for the fabrication of thin film semiconductor materials comprising hydrogenated alloys of silicon and/or germanium. These materials can include nanocrystalline (approximately 100-500 Angstroms) and amorphous (less than approximately 100 Angstroms) structures, and are typically employed in the manufacture of photovoltaic devices, photoconductive devices such as electro photographic members, photo diodes, photo transistors, and other semiconductor devices. As detailed above, the present invention recognizes that VHF energized plasma deposition processes may be implemented utilizing parameters outside the range taught by the prior art, and that operating outside of that range provides for the high speed deposition of high quality semiconductors and other thin film materials.

In a process of the present invention, a cathode and a substrate are disposed in a chamber and a process gas, which includes at least one element of the semiconductor material to be deposited, is introduced into the chamber and maintained at a subatmospheric pressure. VHF electromagnetic energy is applied to the cathode and creates a plasma which decomposes the process gas and provides for the deposition of the semiconductor material onto the substrate.

In a typical process of the present invention, deposition is carried out utilizing VHF energy having a frequency of 30-150 MHz at process gas pressures in the range of 0.5-2.0 torr. In a process of the present invention the cathode is spaced from the substrate by a distance in the range of 10-50 millimeters, and in specific embodiments, the cathode substrate spacing is in the range of 20-30 millimeters. A specific process is carried out with a cathode substrate spacing of approximately 22-28 millimeters. In many instances, the cathode and substrate comprise generally planar bodies disposed in a parallel, spaced apart relationship. However, the present invention may be used with otherwise configured systems.

In a typical process for the preparation of thin film hydrogenated alloys of silicon and/or germanium, deposition rates of at least 5 angstroms per second are achieved. Typically, the depositions occur in the range of 5 to 20 angstroms per second. Most typically, deposition rates exceed 5 angstroms per second, and in specific instances run in the range of 5-10 angstroms per second, with 8 angstroms per second being one typical value for the deposition rate. This compares to deposition rates of approximately 1-3 angstroms per second in a comparable RF energized process. In the present invention, substrate temperatures are maintained below 300° C. As discussed above, the prior art generally teaches away from the use of low substrate temperatures in a high rate deposition process.

As is known in the art, the deposition process of the present invention may be implemented in a variety of embodiments. In particular instances, the substrate is maintained at a ground potential, while in other instances, the substrate is biased so as to have a positive or negative charge relative to the substrate. Such prior art features may be incorporated into the process of the present invention. The present invention may be implemented in conjunction with depositions onto a fixed, nonmoving substrate or in connection with a continuous process wherein a web of substrate material is continuously advanced through a deposition chamber, past one or more fixed cathodes so as to sequentially deposit a substrate material thereonto. Again, the present invention may be implemented in accord with such continuous processes. As is also known in the art, continuous deposition processes may be carried out utilizing a number of deposition stations, some of which may be energized by microwave energy, some by RF energy and some by VHF energy. Again, all of these various embodiments may incorporate the VHF deposition process of the present invention; and, as noted above, the cathode-substrate spacing used in the present invention is compatible with the spacing used in typical RF deposition processes, and hence provides significant advantages in the operation of a multistation continuous process.

It is surprising and unexpected that the process of the present invention produces very high quality semiconductor materials at a high deposition rate. The quality of the material, as is evidenced by measured properties and performance characteristics, is at least as good as material prepared under low deposition rate RF energized processes. For example, in the case of hydrogenated silicon and silicon-germanium alloys, materials produced in accord with the high speed VHF process of the present invention have defect densities and hydrogen content levels and stability when incorporated into photovoltaic cells, which are comparable to, or exceed, properties manifested by similar semiconductor materials prepared in an RF process under low deposition rate conditions.

In addition, it appears that semiconductor materials prepared by the process of the present invention, in at least some instances, exhibit microstructural features which differ from those found in similar materials prepared by RF processes. In this regard, the materials of the present invention, when analyzed by x-ray scattering, appear to have a high density of microvoids, as compared to RF deposited materials. In the prior art, an increase in the microvoid content of hydrogenated silicon or silicon-germanium alloy has been correlated with decreased material performance. In an experimental series, hydrogenated silicon-germanium alloys were prepared by the VHF process of the present invention at a deposition rate of approximately 8 angstroms per second, and comparable materials were prepared in a low rate RF process at approximately 1 angstrom per second, and in a high rate RF process at approximately 5 angstroms per second. The low rate RF material manifested the lowest apparent void density; the high rate material of the VHF process of the present invention manifested the highest apparent void density, and the high rate RF material had an intermediate void density. Evaluation of the materials indicated that despite the data suggesting high microvoid density, the quality of the material produced in the high rate VHF process of the present invention was at least as good as that in the low rate RF process of the prior art. The high rate RF material showed the poorest material quality.

While not wishing to be bound by speculation, Applicant believes that the x-ray scattering data establishes that the material of the present invention has a significant anisotropy in its structure, as is suggested by, and compatible with, the x-ray scattering data. This anisotropy is indicative of a columnar microstructure wherein the material is configured as a plurality of columns separated from one another, at least in part, by microvoids, and extending through the thickness of the semiconductor layer. In contrast, data does not suggest that the prior art materials manifest this type of a microstructure.

### EXPERIMENTAL

In a first experimental series, as summarized in Table 1 hereinbelow, five separate samples of a hydrogenated silicon-germanium alloy were prepared. The first three samples (9169, 9214, 9241) were prepared in an RF energized plasma deposition process at deposition rates of 1 angstrom per second, 4.6 angstroms per second and 4.6 angstroms per second respectively as indicated on the table.

In this first experimental series, the RF deposited sample 9169 was prepared in an RF energized process at 13.56 MHz. The process gas pressure was maintained at 1.0 torr, the substrate was maintained at 280° C., and a process gas mixture was flowed into the deposition chamber. The flow rates for the components of the process gas were: SiH₄ 12 sccm; GeH₄ 0.56 sccm; H₂ 200 sccm. The deposition was carried out for 32,450 seconds. The 9214 sample was deposited in the same apparatus at a pressure of 1.0 torr and a substrate temperature 280° C. Flow rates for the process gas were: SiH₄ 12 sccm; GeH₄ 0.56 sccm; H₂ 100 sccm. Deposition time was 7,200 seconds. The third sample 9241 was deposited in the same apparatus, under the same conditions as the 9214 sample, except that the substrate temperature was maintained at 350° C.

Two samples of material were prepared in accord with the present invention (3D3768, 3D3769) at deposition rates of 4 angstroms per second and 9 angstroms per second respectively. Sample 3D3768 was prepared in a plasma deposition apparatus energized with VHF energy at a frequency of 60 MHz. Pressure in the apparatus was maintained at 1.0 torr and the deposition substrate was spaced from the cathode by a distance approximately 15 millimeters. Substrate temperature was maintained at 275° C. A process gas mixture was flowed into the chamber and flow rates were as follows: SiH₄ 112.5 sccm; GeH₄ 19 sccm; H₂ 2,000 sccm. The deposition was carried out for 4,600 seconds. The 3D3769 sample was deposited in the same apparatus with a cathode substrate spacing of 15 millimeters. The substrate was maintained at 275° C. The flow rates for the process gas components were: SiH₄ 225 sccm; GeH₄ 40 sccm; H₂ 2,000 sccm. Deposition time was 1,600 seconds.

Defect density is one indicator of material quality of a semiconductor material. Table 1 lists the average defect density of the various materials, following light soaking for 50 hours under AM 1.5 illumination. And as will be seen from Table 1, the defect density of materials prepared at high rates in accord with the present invention is slightly lower than that of the material deposited at 1 angstrom per second in the RF process. It is also notable that there is no increase in the defect density of the material of the present invention as the deposition rate rose from 4 to 9 angstroms per second. In contrast, the defect density of the two samples of material deposited at 4.6 angstroms per second in the RF process was higher than that of any of the other samples.

TABLE 1

| Sample | Type (Rate) | Defect Density |
|---|---|---|
| 9169 | RF (1 Å/s) | 9 × 10¹⁵ cm⁻³ |
| 9214 | RF (4.6 Å/s) | 1.8 × 10¹⁶ cm⁻³ |
| 9241 | RF (4.6 Å/s) | 2.1 × 10¹⁶ cm⁻³ |
| 3D3768 | VHF (4 Å/s) | 8 × 10¹⁵ cm⁻³ |
| 3D3769 | VHF (9 Å/s) | 7 × 10¹⁵ cm⁻³ |

In a second experimental series, as is summarized in Table 2, five samples of hydrogenated silicon-germanium material were prepared. Samples 16553, 16552 and 16841 were prepared by a RF energized deposition process as follows. Sample 16553 was prepared by a RF deposition process carried out at 13.56 MHz at a pressure of 1.0 torr. The substrate was maintained at a temperature of 320° C. The components of the process gas were flowed through the deposition chamber at the following rates: SiH₄ 10.6 sccm; GeH₄ 1.06 sccm; H₂ 130 sccm. The deposition was carried out for 1,440 seconds. Sample 16552 was deposited at a pressure of 1.0 torr at a substrate temperature of 320° C. The flow rates for the process gas were: SiH₄ 11 sccm; GeH₄ 1.06 sccm; H₂ 130 sccm. Deposition time was 144 seconds. The third sample 16841 was deposited under conditions identical to those used for sample 16552.

Sample 17013 was deposited utilizing VHF energy. In this deposition, the pressure in the deposition chamber was maintained at 3.0 torr. Cathode-substrate spacing was approximately 13 millimeters. Substrate temperature was 290° C. The flow rates for the process gas were: SiH₄ 4 sccm; GeH₄ 1.25 sccm; H₂ 200 sccm. Deposition was carried out for 120 seconds.

The materials prepared by the foregoing depositions were incorporated as the intrinsic layer of p-i-n type photovoltaic cells. These cells were of conventional configuration and comprised a stainless steel substrate having an aluminized back reflector layer disposed thereupon, and a ZnO layer atop the aluminized layer. Disposed upon the ZnO layer was an amorphous layer of n-doped hydrogenated silicon. Disposed thereatop was a substantially intrinsic layer of amorphous, hydrogenated silicon-germanium semiconductor material prepared in accord with the foregoing. Disposed atop the intrinsic layer was a layer of p-doped, nanocrystalline, hydrogenated silicon. A top electrode contact of a transparent electrically conductive oxide material such as indium tin oxide was disposed thereatop to complete the cell Photovoltaic cells of this type are typical of cells used as bottom and middle cells in double and triple tandem photovoltaic devices. The thus prepared cells were evaluated with regard to open circuit voltage, fill factor, short circuit current, and efficiency, all of which are considered indicators of material quality. It is notable that The cells produced utilizing the VHF deposited semiconductor material of the present invention which was deposited at 10 angstroms per second have performance characteristics which are equivalent to those of the cell which includes the RF material deposited at 1 angstrom per second. In contrast, cells which incorporate semiconductor material deposited by the RF process at 10 angstroms per second have lower performance characteristics. What this demonstrates is that the present invention provides for a ten-fold increase in deposition rate of high quality photovoltaic semiconductor materials, and this increase translates into higher throughput and/or more compact deposition machines.

In a further evaluation, the hydrogen concentration of the semiconductor material was evaluated utilizing a hydrogen evolution technique wherein release of hydrogen from the material as it is heated is measured. On this basis, the concentration of hydrogen in the deposited material was determined. As will be seen from the data on Table 2, the hydrogen content of the low rate RF material and the high rate VHF material of the present invention are very similar, while the hydrogen content of the high speed RF material is notably higher.

TABLE 2

| | | | | | | | | Hydrogen |
|---|---|---|---|---|---|---|---|---|
| Run | | Rate | Voc | | Jsc | Efficiency | Thickness | Concentration |
| No. | Plasma | (Å/s) | (V) | FF | (mA/cm2) | (%) | (nm) | (%) |
| 16553 | RF | 1 | 0.65 | 0.54 | 20.0 | 6.9 | 1348 | 11.7 |
| 16552 | RF | 10 | 0.63 | 0.51 | 17.7 | 5.7 | 1329 | 17.4 |
| 16841 | RF | 10 | 0.64 | 0.51 | 18.6 | 6.1 | 1300 | 16.9 |
| 17013 | VHF | 10 | 0.66 | 0.50 | 19.9 | 6.3 | 1306 | 12.4 |

As will be seen from the foregoing, the present invention provides for a high speed VHF deposition process for the preparation of semiconductor materials utilizing a set of operational parameters which depart from conventional wisdom. The process of the present invention is operative to provide a high quality semiconductor material which is at least comparable to the best materials produced by low deposition rate RF processes. As such, the present invention has significant utility in the large scale production of semiconductor devices.

In a further experimental series, the materials of the present invention were incorporated into various tandem photovoltaic cells, and performance characteristics including photo degradation of the cells was measured. As is known in the art, tandem photovoltaic devices comprise a series of individual photovoltaic cells stacked in an optical and electrical series relationship. In most instances, the tandem devices are comprised of two or three stacked cells, and are respectively referred to as dual tandem devices or triple tandem devices. In tandem devices, the band gap of the materials comprising the stacked cells is often varied so that the bottommost, and in some instances, the middle cells, are fabricated from narrower band gap materials than is the topmost cell. In this manner, absorption of shorter wavelength light takes place in the upper portions of the stacked device and longer wavelength light is absorbed in the lower portions of the device. For example, in devices fabricated from silicon based materials, the intrinsic layer of a topmost cell is generally fabricated from a hydrogenated silicon material, while the bottommost cell is fabricated from a hydrogenated silicon-germanium material. In the instance of a triple tandem device, the middle cell may also be fabricated from a silicon-germanium material generally having a somewhat lower germanium content than the bottommost layer. All of such devices are known in the art.

In the present experimental series, tandem photovoltaic devices were fabricated from a stacked series of p-i-n type photovoltaic cells as generally described above. The stacked series of cells was disposed upon a substrate having an aluminized back reflector layer disposed thereupon, and a ZnO layer atop the aluminized layer. Disposed upon the ZnO layer was an amorphous layer of n-doped hydrogenated silicon. Disposed thereatop was a substantially intrinsic layer of an amorphous, hydrogenated, silicon-germanium semiconductor material, and disposed thereatop was a layer of p-doped nanocrystalline hydrogenated silicon. Thereatop was another layer of n-doped hydrogenated silicon, a superposed layer of substantially intrinsic amorphous, hydrogenated silicon-germanium, and a further layer of p-doped nanocrystalline hydrogenated silicon. Thereatop was another amorphous layer of n-doped hydrogenated silicon with a layer of substantially intrinsic, amorphous, hydrogenated silicon deposited thereupon. A final layer of p-doped nanocrystalline, hydrogenated silicon was deposited thereatop so as to complete the stack of three p-i-n cells. A top electrode contact of a transparent electrically conductive oxide material such as indium tin oxide was disposed atop the stack. In this experimental series, all of the intrinsic layers were prepared by a VHF deposition process as detailed above. Two triple tandem devices were prepared in accord with the foregoing, the first being designated 3D4994 and the second being designated 3D5000. The performance characteristics of the devices in terms of maximum power output (Pmax), short circuit current (Jsc), open circuit voltage (Voc), fill factor (FF), and efficiency (Eff) were measured. Thereafter, the devices were light soaked (L.S.) for a period of 1006 hours under simulated A.M. 1.5 illumination, under open circuit conditions. The properties of the light soaked devices were then measured, and the amount of photo degradation, under open circuit conditions, was determined. Results of these evaluations are summarized in Table 3 hereinbelow.

TABLE 3

| | | LS time | Size | Pmax | Jsc | Voc | | Eff |
|---|---|---|---|---|---|---|---|---|
| Cell# | Cell structure | [hrs] | [cm²] | [W] | [mA/cm²] | [V] | FF | [%] |
| 3D4994 | a-Si:H/a-SiGe:H/a-SiGe:H | 0 | 464 | 4.45 | 5.96 | 2.33 | 0.69 | 9.59 |
| initial | triple-junction | | | | | | | |
| 3D4994 | a-Si:H/a-SiGe:H/a-SiGe:H | 1006 | 464 | 4.22 | 5.96 | 2.28 | 0.67 | 9.10 |
| stable | triple-junction | | | | | | | |
| Degradation | | | | 5.1% | 0.0% | 2.0% | 3.1% | 5.1% |
| (%) | | | | | | | | |
| 3D5000 | a-Si:H/a-SiGe:H/a-SiGe:H | 0 | 464 | 4.63 | 6.23 | 2.34 | 0.69 | 9.98 |
| initial | triple-junction | | | | | | | |
| 3D5000 | a-Si:H/a-SiGe:H/a-SiGe:H | 1006 | 464 | 4.39 | 6.21 | 2.29 | 0.67 | 9.46 |
| stable | triple-junction | | | | | | | |
| Degradation | | | | 5.2% | 0.3% | 2.0% | 3.0% | 5.2% |
| (%) | | | | | | | | |

As will be seen, the resultant photo degradation manifested by the materials of the present invention, under open circuit conditions, is 5.1% for the 3D4994 device and 5.2% for the 3D5000 device. It is typical in devices fabricated with prior art materials to see photo degradations of approximately 15% under similar test conditions.

In yet another experimental series, the photo degradation of dual and triple tandem photovoltaic devices, under open circuit conditions, was evaluated. As depicted in Table 4 hereinbelow, the first triple tandem device was fabricated as per the devices of Table 3. This device included a bottom cell having an intrinsic layer of a hydrogenated SiGe material, a middle cell which also included an intrinsic layer of a hydrogenated SiGe semiconductor and a top cell which included an intrinsic layer of a hydrogenated Si semiconductor material. All of the intrinsic layers in this device were prepared by a VHF energized deposition process. The initial efficiency of this device was 10.1%, and following 400 hours of light soaking under A.M. 1.5 illumination for 4 hours, the efficiency decreased to 9.5%, and the net degradation of this device, under open circuit conditions, was 6%. The second device in the table was a dual tandem photovoltaic device which included a bottom cell having a hydrogenated SiGe intrinsic layer and a top cell which included a hydrogenated Si semiconductor layer. The initial efficiency of this device was 10.7% and the efficiency following 400 hours of light soaking under A.M. 1.5 illumination was 9.5%, and the overall degradation of the device upon light soaking was 10%. The third entry in the table is a reference sample which comprises a triple tandem device generally similar to that of the first entry, except that the intrinsic layers were all deposited in an RF deposition process as described above. The initial efficiency of this device was 9.7% and the efficiency degraded to 8.4% following 400 hours of light soaking at A.M. 1.5 illumination. The net degradation of this device, under open circuit conditions, was 13%.

TABLE 4

| | | Initial | Light-soaked | |
|---|---|---|---|---|
| | Size | efficiency | efficiency (%) | |
| | (cm²) | (%) | @ 400 hrs | Degradation |
| VHF triple a-Si:H/a- | 464 | 10.1 | 9.5 | 6% |
| SiGe:H/a-SiGe:H | | | | |
| VHF double a-Si:H/a- | 464 | 10.7 | 9.5 | 10% |
| SiGe:H | | | | |
| RF reference a-Si:H/a- | 464 | 9.7 | 8.4 | 13% |
| SiGe:H/a-SiGe:H | | | | |

For purposes of illustration, the present invention has been described primarily with regard to hydrogenated silicon and silicon-germanium semiconductors prepared in a specific VHF deposition process. However, materials of the present invention are of a novel structure and can be prepared by other deposition processes, including RF and microwave processes. Also, the principles of the present invention may be utilized for the production of other types of semiconductors as well as for any other plasma deposition process. The foregoing discussion, description and examples are illustrative of some specific embodiments of the present invention, but are not meant to be limitations upon the practice thereof. Modifications and variations will be readily apparent to those of skill in the art. It is the following claims, including all equivalents, which define the scope of the invention.

1. A hydrogenated silicon-germanium semiconductor alloy having a defect density of less than 10¹⁶ cm⁻³.

2. (canceled)

3. The semiconductor alloy of claim 1, wherein the defect density is less than 8×10¹⁵ cm⁻³.

4. The semiconductor alloy of claim 1, wherein the defect density is approximately 7×10¹⁵ cm⁻³.

5. The semiconductor alloy of claim 1, wherein the hydrogen content thereof is less than 15%.

6. The semiconductor alloy of claim 1, further characterized in that when said alloy comprises the i layer of a p-i-n type photovoltaic cell, that cell manifests a photo-induced degradation, under open circuit conditions, of less than 15% when exposed to A.M. 1.5 illumination for 1,000 hours at 50° C.

7. The semiconductor alloy of claim 1, further characterized in that when said alloy comprises one of the i layers in a triple junction photovoltaic cell having an initial efficiency of at least 9%, that cell manifests a photo-induced degradation, under open circuit conditions, of less than 10% when exposed to A.M. 1.5 illumination for 1,000 hours at 50° C.

8. (canceled)

9. The semiconductor alloy of claim 1, wherein at least a portion of said semiconductor material has a microstructure configured as a plurality of columns separated by microvoids.

10. A photovoltaic device which includes the semiconductor alloy of claim 1.

11. A hydrogenated silicon based semiconductor alloy characterized in that when said alloy comprises the i layer of a p-i-n type photovoltaic cell, that cell manifests a photo-induced degradation, under open circuit conditions, of less than 15% when exposed to A.M. 1.5 illumination for 1,000 hours at 50° C.

12. The semiconductor alloy of claim 1, wherein said alloy is an amorphous hydrogenated silicon-germanium alloy.

13. A hydrogenated, silicon based semiconductor alloy characterized in that when it comprises one of the i layers in a triple junction photovoltaic cell having an initial efficiency of at least 9% that cell manifests a photo-induced degradation, under open circuit conditions, of less than 10% when exposed to A.M. 1.5 illumination for 1,000 hours at 500 C.

14. (canceled)

15. The semiconductor alloy of claim 13, further characterized in that it has a defect density of less than 8×10¹⁵ cm⁻³.

16. The semiconductor alloy of claim 13, further characterized in that it has a defect density of approximately 7×10¹⁵ cm⁻³.

17. The semiconductor alloy of claim 13, wherein the hydrogen content thereof is less than 15%.

18. The semiconductor alloy of claim 13, wherein at least a portion of said semiconductor material has a microstructure configured as a plurality of columns separated by microvoids.

19. A photovoltaic device which includes the semiconductor alloy of claim 13.

20. A hydrogenated silicon based semiconductor alloy having a defect density of less than 10¹⁶ cm⁻³, wherein at least a portion of said semiconductor material has a microstructure configured as a plurality of columns separated by microvoids.

21. The semiconductor alloy of claim 20, wherein the hydrogen content thereof is less than 15%.
